(19) United States
(12) Patent Application Publication
(10) Pub. No.: US 2024/0284630 A1
(43) Pub. Date: Aug. 22, 2024

(54) MEDICAL DEVICE

(71) Applicant: SONY GROUP CORPORATION, TOKYO (JP)

(72) Inventors: TOMOYUKI KUBOTERA, TOKYO (JP); NOBUHISA TOKUNAGA, TOKYO (JP)

(21) Appl. No.: 18/570,081

(22) PCT Filed: Feb. 16, 2022
(86) PCT No.: PCT/JP2022/006057

§ 371 Date: Dec. 14, 2023

(30) Foreign Application Priority Data
Jun. 23, 2021 (JP) 2021-104114

(51) Int. Cl. H05K 7/20

(52) U.S. Cl. CPC H05K 7/20181; H05K 7/20145

(57) ABSTRACT

The present technology relates to a medical device that improves a drip-proof property of a ventilation portion for cooling an inside of a housing with a simple structure. An outside and the inside of the housing are ventilated by a ventilation path in which a plurality of ventilation paths having a longitudinal cross-sectional shape with a predetermined first direction as a longitudinal direction is arranged along a second direction different from the first direction. The ventilation path is covered with the covering member from the outer side of the housing, and is ventilated to the outside of the housing by the plurality of ventilation paths included in the covering member. The present technology can be applied to a medical monitor or the like.

### TECHNICAL FIELD

The present technology relates to a medical device, and more particularly, to a medical device in which an unevenness such as a screw head of a ventilation portion for cooling the inside of a housing is eliminated to improve a drip-proof property of the ventilation portion with a simple structure.

### BACKGROUND ART

Patent Document 1 discloses a cover that is attached to a ventilation hole of a housing of an electronic device to improve a drip-proof property.

### CITATION LIST

### Patent Document

Patent Document 1: Japanese Patent Application Laid-Open No. 7-212054

### SUMMARY OF THE INVENTION

### Problems to be Solved by the Invention

Since a ventilation portion that allows ventilation between an outside and an inside of a housing for cooling the inside of the housing is a factor in reducing a drip-proof property, it is desired to achieve both the drip-proof property and an air permeability of the ventilation portion with a simple structure.

The present technology has been made in view of such a situation, and an object thereof is to improve the drip-proof property of the ventilation portion for cooling the inside of the housing by the simple structure.

### Solutions to Problems

A medical device according to the present technology is a medical device including: an inner louver that is a ventilation path for ventilation between an outside and an inside of a housing and has a structure in which a plurality of ventilation paths having a longitudinal cross-sectional shape with a predetermined first direction as a longitudinal direction is arranged along a second direction different from the first direction; and a covering member that covers the inner louver from the outer side of the housing and includes the plurality of ventilation paths for ventilation between the outside of the housing and the inner louver.

In the medical device of the present technology, the outside and the inside of the housing are ventilated by the plurality of ventilation paths having the longitudinal cross-sectional shape with the predetermined first direction as the longitudinal direction, the plurality of ventilation paths being arranged along the second direction different from the first direction. The ventilation path is covered with the covering member from the outer side of the housing, and is ventilated to the outside of the housing by the plurality of ventilation paths included in the covering member.

### BRIEF DESCRIPTION OF DRAWINGS

FIG. 1 is a rear perspective view representing an embodiment of a monitor to which the present technology is applied.

FIG. 2 is a perspective view from the back side illustrating a state in which an outer louver is removed from a rear cover.

FIG. 3 is a perspective view from the back side illustrating the rear cover.

FIG. 4 is a perspective view from the front side illustrating the rear cover.

FIG. 5 is an enlarged view illustrating a periphery of an opening portion of the rear cover.

FIG. 6 is a perspective view exemplifying from the back side a back surface portion of a monitor to which the present technology is not applied.

FIG. 7 is an enlarged perspective view illustrating a periphery of an inner louver of an exhaust portion.

FIG. 8 is a perspective view illustrating a cross-section of the inner louver cut along a vertical direction.

FIG. 9 is a cross-sectional view illustrating a part of a louver board in a case where the inner louver is cut along the vertical direction.

FIG. 10 is a cross-sectional view describing action of the inner louver.

FIG. 11 is a cross-sectional view describing action of the inner louver.

FIG. 12 is a view describing a structural condition of the inner louver.

FIG. 13 is a view describing an inclination angle in front-rear and left-right directions required for a drip-proof test corresponding to IPX2 as a drip-proof performance.

FIG. 14 is a view from the rear side simply illustrating the inner louver of an intake portion.

FIG. 15 is a back view from the rear side illustrating the outer louver.

FIG. 16 is a perspective view from below illustrating a cross-section of the outer louver in a case where the outer louver is cut along a horizontal direction.

FIG. 17 is a view describing a mounting structure of the outer louver on the rear cover.

FIG. 18 is a view illustrating a cross-section of positions of a projection and a locking portion of the outer louver.

FIG. 19 is an enlarged cross-sectional view illustrating a periphery of the projection in FIG. 18.

FIG. 20 is an enlarged cross-sectional view illustrating a periphery of the locking portion in FIG. 18.

FIG. 21 is a view illustrating a procedure when the outer louver is attached to the opening portion of the rear cover.

FIG. 22 is a view illustrating the procedure when the outer louver is attached to the opening portion of the rear cover.

FIG. 23 is a view illustrating the procedure when the outer louver is attached to the opening portion of the rear cover.

FIG. 24 is a view illustrating a procedure when removing the outer louver from the opening portion of the rear cover.

FIG. 25 is a view illustrating a state of work when using a cloth to clean and disinfect the exhaust portion of the back surface portion of the monitor.

FIG. 26 is a view illustrating a state of work when using a cloth to clean and disinfect the exhaust portion of the monitor of FIG. 6 to which the present technology is not applied.

### MODE FOR CARRYING OUT THE INVENTION

Hereinafter, an embodiment of the present technology will be described with reference to the drawings.

### <Embodiment of a Monitor>

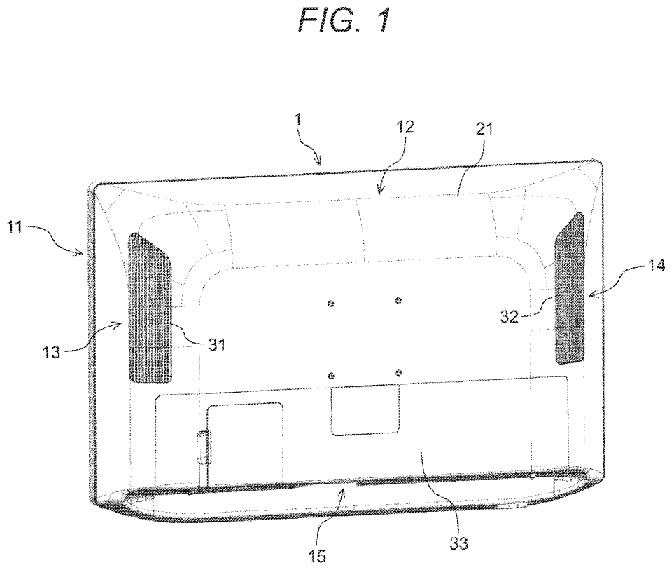

FIG. 1 is a rear perspective view representing an embodiment of a monitor to which the present technology is applied.

A monitor 1 in FIG. 1 is, for example, a medical (for medical use) monitor that displays a medical image or the like at a medical site, and is a monitor classified as a medical device. An image display panel such as a liquid crystal panel or an organic EL panel is disposed on a front surface portion 11 (not illustrated) of the monitor 1. The image display panel is not limited to a specific type.

An intake portion 13, an exhaust portion 14, and a connector portion 15 are disposed on a back surface portion 12 of the monitor 1 illustrated in FIG. 1. The intake portion 13 is provided on the left side of the back surface portion 12 (on the left side of the back surface portion 12 when the monitor 1 is viewed from the back side). The intake portion 13 sucks air from the outside of the monitor 1 to the inside of the monitor 1. The exhaust portion 14 is provided on the right side of the back surface portion 12. The exhaust portion 14 discharges air inside the monitor 1 to the outside of the monitor 1. The intake portion 13 and the exhaust portion 14 are ventilation portions that ventilate the outside and the inside of the monitor 1, and the inside of the monitor 1 is cooled by the intake and exhaust of the intake portion 13 and the exhaust portion 14. Note that a fan that sucks air from the intake portion 13 or a fan that discharges air from the exhaust portion 14 is provided inside the monitor 1. However, there may be a case where a fan for intake or exhaust is not provided inside the monitor 1. The intake portion 13 and the exhaust portion 14 may be ventilation portions for ventilation which are not limited to the use of either intake air or exhaust air.

The connector portion 15 includes a connector (not illustrated) or the like that connects various cables. For example, the cables connected to the connector of the connector portion 15 include a cable for transmitting a power source from a power outlet and a cable for transmitting an input signal such as a video signal or an audio signal to the monitor 1 from an external device.

As a part of a housing that covers the entire back side of the monitor 1, a rear cover 21 is disposed on the back surface portion 12 of the monitor 1. The rear cover 21 covers internal components of the monitor 1 with the front surface portion 11. Note that the front surface portion 11 is configured from the image display panel (not illustrated), a frame thereof, and the like.

An outer louver 31, an outer louver 32, and a connector cover 33 are detachably attached to a front surface of the rear cover 21 with respect to the rear cover 21. The outer louver 31 is disposed in the intake portion 13, the outer louver 32 is disposed in the exhaust portion 14, and the outer louvers 31 and 32 are respectively disposed as covering members that cover the inner louvers 41 and 42 to be described later, and suppress entry of water droplets or the like to the inside of the monitor 1. Furthermore, the front surfaces of the outer louvers 31 and 32 have a shape following the front surface of the rear cover 21, the shape contributing to an improvement of cleaning performance.

The connector cover 33 is disposed on the connector portion 15 and shields exposure of the connector portion 15 to the outside of the connector or the like.

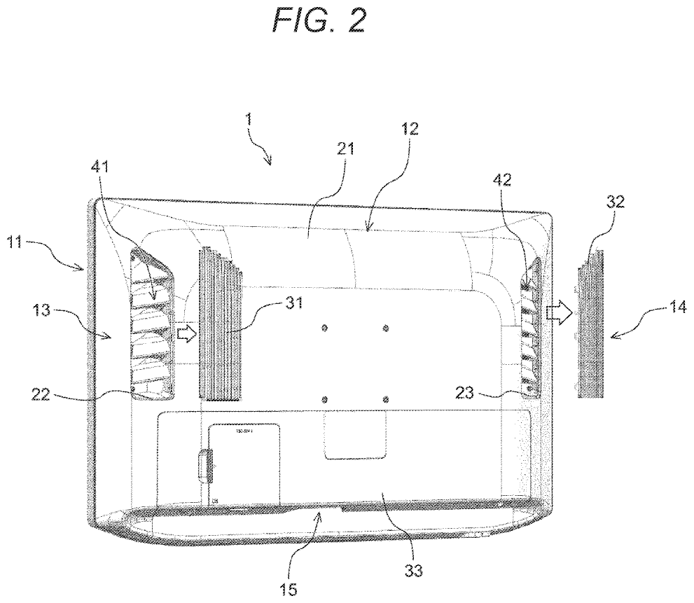

FIG. 2 is a perspective view from the back side illustrating a state in which the outer louvers 31 and 32 are removed from the rear cover 21. Note that, in the drawing, the same parts as those in FIG. 1 are denoted by the same reference numerals, and the description thereof will be omitted.

In FIG. 2, the outer louver 31 of the intake portion 13 is in a state of being removed from the opening portion 22 formed in the rear cover 21. The outer louver 32 of the exhaust portion 14 is in a state of being removed from the opening portion 23 formed in the rear cover 21. The outer louvers 31 and 32 are detachably attached to the opening portions 22 and 23, respectively.

In the opening portion 22, the inner louver 41 is disposed as a part of the intake portion 13. In the opening portion 23, the inner louver 42 is disposed as a part of the exhaust portion 14. If attached to the opening portions 22 and 23, the outer louvers 31 and 32 cover the front sides of the inner louvers 41 and 42, respectively (see FIG. 1). With this arrangement, the intake portion 13 is configured by a double louver of the outer louver 31 and the inner louver 41. The exhaust portion 14 is configured by a double louver of the outer louver 32 and the inner louver 42. Since both the intake portion 13 and the exhaust portion 14 are configured by the double louvers, a drip-proof property is improved.

Note that, in the description of the configurations and the like of the rear cover 21, the intake portion 13, and the exhaust portion 14, terms such as front, rear, upper, lower, left, and right are used in a case of describing positions and directions. In this case, in the monitor 1 with the rear cover 21 assembled, a direction from the front side to the back side of the monitor 1 is a direction from the front to the rear (front-rear direction), a direction from the upper side to the lower side of the monitor 1 is a direction from the upper side to the lower side (up-down direction), and a direction from the left side to the right side of the monitor 1 in a case where the monitor 1 in an upright state is viewed from the back side (rear side) is a direction from the left to the right (left-right direction).

### <Description of the Rear Cover 21>

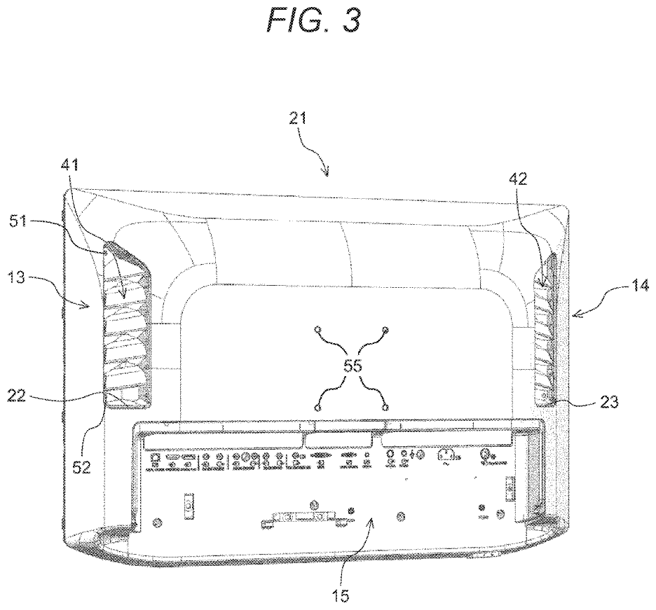

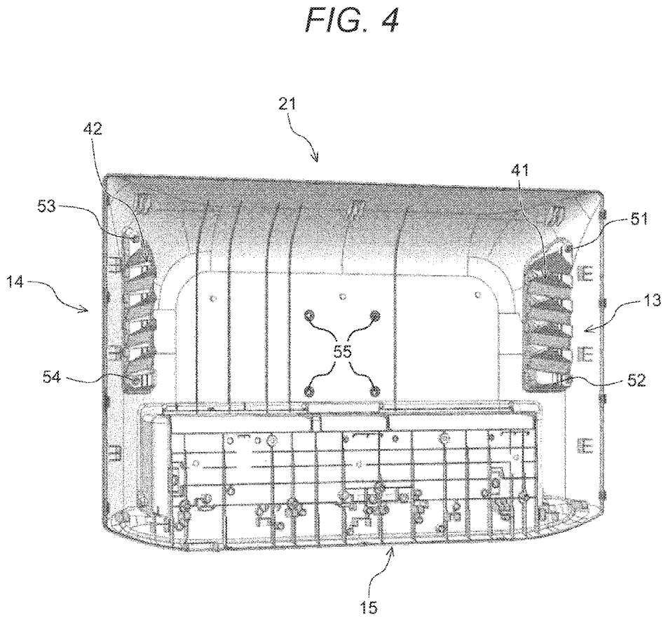

FIG. 3 is a perspective view from the back side (rear side) illustrating the rear cover 21. FIG. 4 is a perspective view from the front side illustrating the rear cover 21.

In FIGS. 3 and 4, the rear cover 21 is in a state of being removed from the front surface portion 11 of the monitor 1. The outer louver 31 and the outer louver 32 that are detachable from the rear cover 21 are also removed from the rear cover 21, and the connector cover 33 that is detachable from the rear cover 21 is also removed from the rear cover 21. That is, the rear cover 21 in FIGS. 3 and 4 represents a component (housing) of the monitor 1 integrally formed by, for example, a synthetic resin.

In a case where the rear cover 21 is attached to the front surface portion 11 and assembled as a part of the monitor 1, the rear cover 21 has a front surface (rear surface) represented in FIG. 3 exposed to the outside of the monitor 1 and a rear surface (front surface) represented in FIG. 4 facing the inside of the monitor 1.

In FIG. 3, the opening portion 22 of the intake portion 13 is formed on the left side of the rear cover 21. The opening portion 23 of the exhaust portion 14 is formed on the right side of the rear cover 21. Note that, since the opening portion 22 of the intake portion 13 and the opening portion 23 of the exhaust portion 14 are formed substantially symmetrically and have a similar structure, matters commonly applied to the intake portion 13 and the exhaust portion 14 will be described only for one, and a description of the other will be omitted. However, the opening portion 22 of the intake portion 13, the exhaust portion 14, and the opening portion 23 do not necessarily have to be symmetrical.

In FIGS. 3 and 4, the inner louver 41 constituting the intake portion 13 is integrally formed with the rear cover 21 in the opening portion 22. In the opening portion 23, an inner louver 42 constituting the exhaust portion 14 is integrally formed with the rear cover 21.

Screw insertion holes 51 and 52 are provided in the inner side of the opening portion 22, and screw insertion holes 53 and 54 are provided in the inner side of the opening portion 23. Four screw insertion holes 55 are provided in a center portion of the rear cover 21. In a case where a stand for supporting the monitor 1 is attached to the monitor 1, screws for fastening the stand and the monitor 1 are inserted into the screw insertion holes 55.

Screws for attaching the rear cover 21 to the front surface portion 11 of the monitor 1 are inserted into the screw insertion holes 51 to 54. In a case where the rear cover 21 is aligned with a mounting position on the front surface portion 11, screw holes are formed at positions on the front surface portion 11 where the screw insertion holes 51 to 54 face each other. Note that, in the case of the front surface portion 11, the front surface portion 11 also includes the internal components of the monitor 1 fixed to the front surface portion 11 by screw fastening or the like. The screws are inserted into the screw insertion holes 51 to 54 and are tightened into the screw holes of the front surface portion 11 facing each of the screw insertion holes 51 to 54, so that the rear cover 21 is attached to the front surface portion 11 by screw fastening.

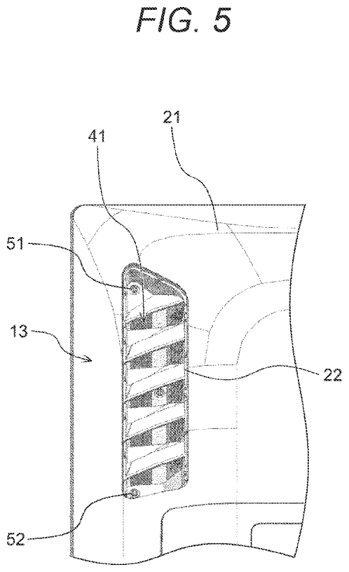

FIG. 5 is an enlarged view illustrating a periphery of the opening portion 22 of the rear cover 21. In FIG. 5, the screw insertion holes 51 and 52 are respectively disposed in an upper portion and a lower portion of the inner louver 41 integrally formed on the inner side of the opening portion 22. The screws (head portions of the screws) inserted into these screw insertion holes 51 and 52 are not revealed to the front surface of the rear cover 21 due to the outer louver 31 attached to the opening portion 22. A similar situation applies to the screw insertion holes 53 and 54 in the opening portion 23.

With this arrangement, the work of cleaning the monitor 1 using a cloth (including a case where the purpose is at least one among the removal of deposits, disinfection, and sterilization) is not hindered by an unevenness of the screws generated on the back surface portion 12 of the monitor 1, and a situation in which the efficiency of the cleaning work is reduced is prevented. That is, the cleaning performance of the monitor 1 is improved.

<Rear Cover Mounting Structure of a Monitor 501 to which the Present Technology is not Applied>

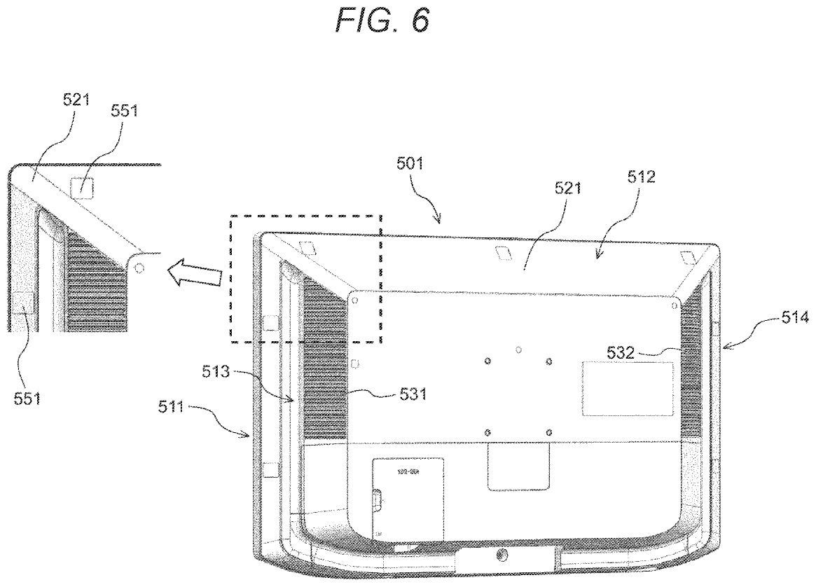

FIG. 6 is a perspective view exemplifying from the back side the back surface portion of a monitor to which the present technology is not applied. The monitor 501 in FIG. 6 is, for example, a medical monitor. Regarding the monitor 501, only a part of the configuration will be described, and the other part is common to the monitor 1 in FIG. 1. In the monitor 501 of FIG. 6, a back surface portion 512 is provided with an intake portion 513 that sucks outside air to the inside of the monitor 501 and an exhaust portion 514 that discharges the air inside the monitor 501 to the outside. The rear cover 521 covering the entire back surface portion 512 of the monitor 501 is provided with a louver 531 constituting the intake portion 513 and a louver 532 constituting the exhaust portion 514. The louvers 531 and 532 are integrally formed with the rear cover 521.

Screw fastening portions 551 are provided at a plurality of positions in a peripheral edge portion of the rear cover 521, and the screw fastening portions 551 are illustrated in the upper left of the drawing in an enlarged view of a part of the periphery of the plurality of positions. The screw fastening portion 551 is provided with a recess formed in a recessed shape and a screw insertion hole penetrating from a bottom surface of the recess toward the front surface portion 511. The screw inserted through the screw insertion hole is fastened to the screw hole of the front surface portion 511, whereby the rear cover 521 is fixed to the front surface portion 511. A cap is attached to an opening on the front side of the recess of the screw fastening portion 551 to cover the head of the screw.

With this arrangement, the work of cleaning the monitor 501 using the cloth is hindered by a gap or a step generated in the cap of the screw fastening portion 551, and a situation is generated in which the work efficiency is reduced. In the monitor 1 of FIG. 1, since a structure such as the screw fastening portion 551 of the monitor 501 can be eliminated, the work efficiency of the cleaning work can be improved.

### <Description of the Inner Louvers 41 and 42>

The structure or the like of the inner louvers 41 and 42 illustrated in FIG. 2 or the like will be described using the inner louver 42 of the exhaust portion 14 as an example.

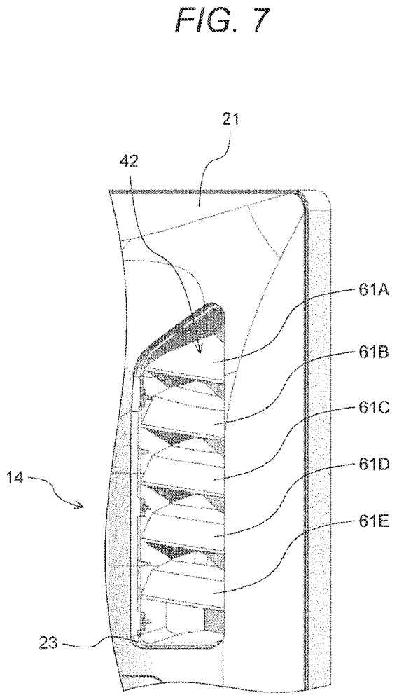

FIG. 7 is an enlarged perspective view illustrating a periphery of the inner louver 42 of the exhaust portion 14. The inner louver 42 in FIG. 7 has a louver door structure in which a plurality of (five) thin louver boards 61A to 61E is arranged at predetermined intervals in a vertical direction (up-down direction) on the inner side of the opening portion 23 of the rear cover 21. Each of the louver boards 61A to 61E is provided sequentially from a peripheral edge portion of the opening portion 23 of the rear cover 21, and is integrally formed and supported on the rear cover 21. Each of the louver boards 61A to 61E is arranged along a horizontal direction (left-right direction). To be precise, a board surface of each of the louver boards 61A to 61E is inclined in a right oblique downward direction (described later). Note that each of the inner louvers 41 and 42 may be configured separately from the rear cover 21, and may be detachably attached to the rear cover 21 by screw fastening or the like.

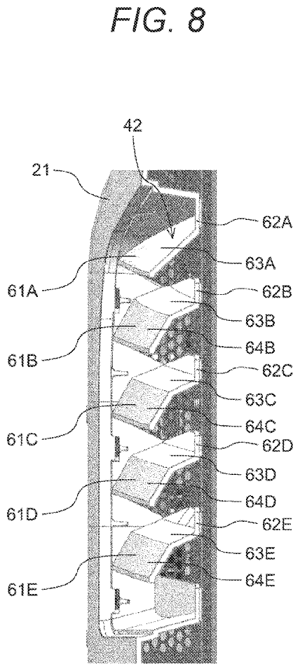

FIG. 8 is a perspective view illustrating a cross-section of the inner louver 42 cut along the vertical direction. In FIG. 8, each of the louver boards 61A to 61E of the inner louver 42 is disposed so as to be inclined obliquely downward toward the rear direction (the rear side in the front-rear direction). Among the louver boards 61A to 61E, the uppermost louver board 61A has a base end portion 62A, a gentle slope portion 63A, and a tip end portion 65A (not illustrated). The base end portion 62A is a part where the board surface is disposed along the up-down direction. The gentle slope portion 63A is a part inclined and extending obliquely downward from the lowermost portion of the base end portion 62A toward the rear direction. The tip end portion 65A is a part extending downward from a front end portion of the gentle slope portion 63A. The tip end portion 65A is not illustrated in FIG. 8 because the vertical width is small.

The louver boards 61B to 61E have a similar shape other than the uppermost portion among the louver boards 61A to 61E. The louver boards 61B to 61E respectively have base end portions 62B to 62E, gentle slope portions 63B to 63E, steep slope portions 64B to 64E, and tip end portions 65B to 65E (not illustrated).

The base end portions 62B to 62E are parts where the board surfaces are disposed along the up-down direction. The gentle slope portions 63B to 63E are parts inclined and extending obliquely downward from the lowermost portions of the base end portions 62B to 62E toward the rear direction. The steep slope portions 64B to 64E are parts inclined and extending obliquely downward from the foremost portions of the gentle slope portions 63B to 63E toward the rear direction and having a steeper slope than the gentle slope portions 63B to 63E. The tip end portions 65B to 65E are parts extending downward from the lowermost portions of the steep slope portions 64B to 64E, respectively. The tip end portions 65B to 65E have a small vertical width, and thus are not illustrated in FIG. 8. Note that, as compared with the other louver boards 61B to 61E, the louver board 61A has the gentle slope portion 63A corresponding to the gentle slope portions 63B to 63E, and does not have a steep slope portion corresponding to the steep slope portions 64B to 64E. The gentle slope portion 63A of the louver board 61A has a steeper slope than the gentle slope portions 63B to 63E of the louver boards 61B to 61E and a gentler slope than the steep slope portions 64B to 64E. However, the louver board 61A may have a similar structure (shape) to the other louver boards 61B to 61E.

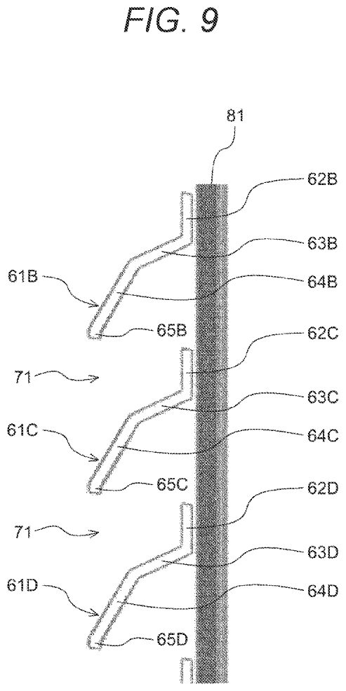

FIG. 9 is a cross-sectional view illustrating only parts of the louver boards 61B to 61D in a case where the inner louver 42 is cut along the vertical direction (up-down direction and front-rear direction).

FIG. 9 illustrates each of the louver boards 61B to 61D of the inner louver 42 and a member 81 of the front surface portion 11 disposed on the front side of the inner louver 42. The member 81 of the front surface portion 11 is a member separate from the rear cover 21, and is, for example, a mesh-like protective member surrounding a periphery of the fan, but is not limited thereto.

Each of the louver boards 61B to 61D has the base end portions 62B to 62D, the gentle slope portions 63B to 63D, the steep slope portions 64B to 64D, and the tip end portions 65B to 65D described in FIG. 8.

An opening (gap portion) 71 is formed between adjacent louver boards of each of the louver boards 61B to 61D (each of the louver boards 61A to 61E), and represents a ventilation path through which air passes in the front-rear and left-right directions. That is, the opening 71 is partitioned by a louver board as a partition between the opening 71 and the adjacent opening 71. Each of the openings 71 has a longitudinal cross-sectional shape whose longitudinal direction is the left-right direction. Note that, assuming that the longitudinal direction of the opening 71 is a first direction, a plurality of the openings 71 is arranged along a second direction different from the first direction. In the present embodiment, the second direction is a direction orthogonal to the first direction, but in the present technology, the second direction may be a direction other than the direction orthogonal to the first direction (a direction different from the first direction). In the present embodiment, the first direction is a direction along a direction (horizontal direction) orthogonal to the vertical direction (gravity direction), but in the present technology, the first direction may be a direction along a direction other than the horizontal direction. In the present embodiment, the second direction is a direction along the vertical direction (gravity direction), but in the present technology, the second direction may be a direction along a direction other than the gravity direction.

Since the inner louver 42 is disposed in the exhaust portion 14 that discharges air, the air passes through each opening 71 from the front side to the rear side (from the right side to the left side in FIG. 9). Note that, in the inner louver 41 of the intake portion 13, air passes through an opening corresponding to the opening 71 from the rear side to the front side.

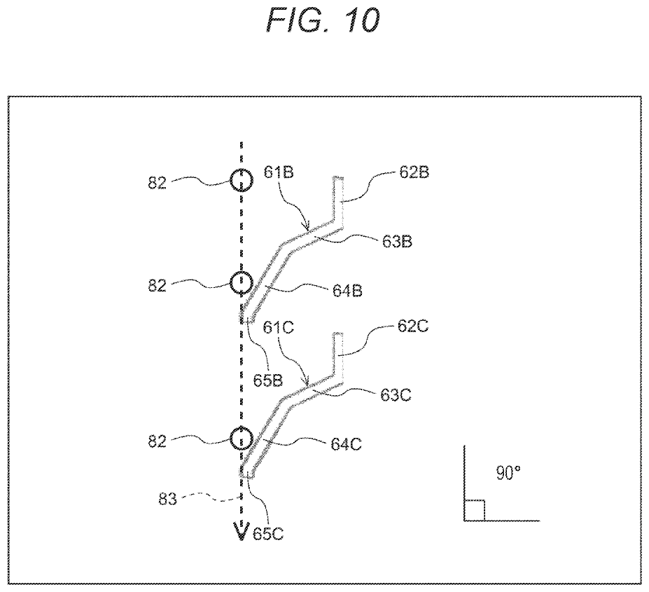

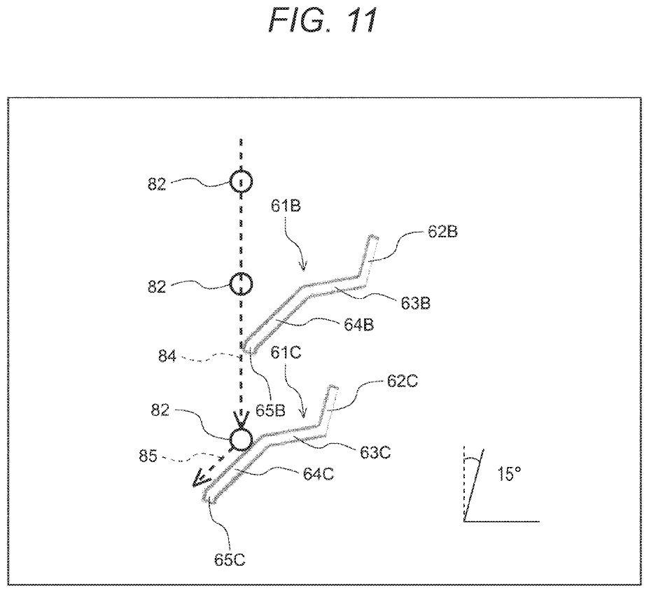

FIGS. 10 and 11 are cross-sectional views describing action of the inner louver 42. FIG. 10 illustrates a case where the monitor 1 is in the upright state, and a normal direction of a surface (screen) of the front surface portion 11 of the monitor 1 is the horizontal direction. FIG. 11 represents a fallen state in which the monitor 1 falls down (tilts) to the front side, and a state in which the monitor 1 falls down to the front side by about 15 degrees, about 15 degrees being the maximum fall angle of the monitor 1 with respect to the upright state.

In FIGS. 10 and 11, the louver boards 61B and 61C are two adjacent louver boards selected from the louver boards 61B to 61E of the inner louver 42, and represent arbitrary adjacent louver boards.

The inner louver 42 mainly has a drip-proof action of preventing water droplets that have passed through the outer louver 32 disposed on the rear side of the inner louver 42 from entering the monitor 1. Since the outer louver 32 as described later has an action of preventing a water droplet from the outside of the monitor 1 from directly entering the inner louver 42, a water droplet that passes through the outer louver 32 and comes into contact with the inner louver 42 is a water droplet that falls from the upper side to the lower side in the up-down direction (gravity direction) mainly by gravity.

In FIGS. 10 and 11, a water droplet 82 represents the water droplet falling in the up-down direction. In FIG. 10, in a case where the monitor 1 is in the upright state, the louver boards 61B and 61C are in a positional relationship in which one of the louver boards is shifted only in the up-down direction by a predetermined distance, and at the very least, positions in the front-rear direction substantially coincide with each other. At this time, the water droplet 82 that has fallen onto the louver board 61B from the upper side falls to the vicinity of the tip end portion 65B of the louver board 61B, and then falls downward to the lower side from the tip end portion 65B along the tip end portion 65B. The water droplet 82 dropped from the tip end portion 65B further drops to the vicinity of the tip end portion 65C of the louver board 61C under the louver board 61B, and then drops downward to the lower side from the tip end portion 65C along the tip end portion 65C. Note that an arrow 83 represents a path of the water droplet 82.

With this arrangement, since the water droplet 82 in contact with the inner louver 42 flows down along a vicinity of the tip end portions 65A to 65E of each of the louver boards 61A to 61E of the inner louver 42, entry of the water droplet into the monitor 1 is prevented.

In FIG. 11, in a case where the monitor 1 is in the fallen state, the louver boards 61B and 61C have a positional relationship in a case where the inner louver 42 falls forward to the front side only by the same fall angle (about 15 degrees) as the monitor 1. That is, the louver boards 61B and 61C are not only in a positional relationship in which one of the louver boards is only shifted in the up-down direction and by a predetermined distance, but also in a positional relationship in which the louver board 61C on the lower side is shifted in the forward direction only by a predetermined distance with respect to the louver board 61B on the upper side. Each of the louver boards 61B and 61C is in a position of being rotated in a clockwise direction in the drawing (the clockwise direction with respect to a rotation axis from right to left) only by an angle corresponding to the fall angle of the monitor 1 with respect to the case where the monitor 1 in FIG. 10 is in the upright state. At this time, the water droplet 82 that has dropped from the upper side to the vicinity of the tip end portion 65B of the louver board 61B drops downward to the lower side from the tip end portion 65B along the tip end portion 65B. The water droplet 82 dropped from the tip end portion 65B drops into the steep slope portion 64C of the louver board 61C under the louver board 61B (drops along a path indicated by an arrow 84). The water droplet 82 that has dropped on the steep slope portion 64C flows along the steep slope portion 64C to the tip end portion 65C (flows along a path indicated by an arrow 85), and drops downward to the lower side from the tip end portion 65C along the tip end portion 65C.

Even in a case where the water droplet 82 falling on the louver board 61B is not in the vicinity of the tip end portion 65B, the water droplet falling along the louver board 61A on the upper side of the louver board 61B is in the range of the steep slope portion 64B of the louver board 61B, similar to the water droplet falling from the louver board 61B to the louver board 61C. Therefore, the water droplet flows along the steep slope portion 64B of the louver board 61B to the tip end portion 65B, and falls from the tip end portion 65B to the louver board 61C on the lower side.

With this arrangement, even in a state where the inner louver 42 falls down to the front side at the maximum fall angle together with the monitor 1, the water droplet 82 in contact with the inner louver 42 flows down along the steep slope portions 64B to 64E and the tip end portions 65B to 65E of each of the louver boards 61B to 61E of the inner louver 42, so that the water droplet is prevented from entering the inside of the monitor 1. Note that an opening through which air passes is not formed on the upper side of the uppermost louver board 61A of the inner louver 42, whereby entry of water droplets into the inside of the monitor 1 from the upper side of the louver board 61A is prevented. The water droplet dropped on the louver board 61A drops in the range of the steep slope portions 64B to 64E and the tip end portions 65B to 65E in the louver boards 61B to 61E on the lower side of the louver board 61A.

### <Design Conditions of the Inner Louver>

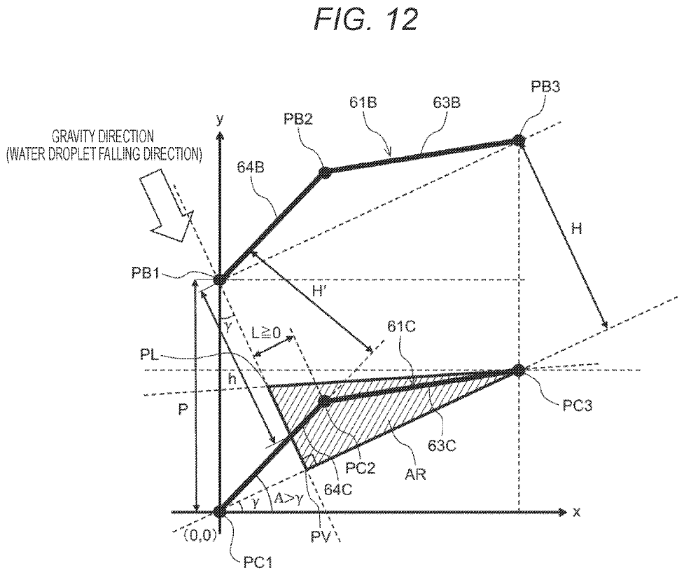

FIG. 12 is a drawing describing structural conditions of the inner louver 42. Note that, as a structural condition of the inner louver 42, only the up-down direction (that is, the arrangement direction of each of the louver boards 61A to 61E) will be described.

In FIG. 12, the louver boards 61B and 61C simply represent the louver boards 61B and 61C of the inner louver 42 in FIGS. 10 and 11. In the louver boards 61B and 61C, the base end portions 62B and 62C and the tip end portions 65B and 65E are not prioritized as structural conditions of the inner louver 42, and thus, are omitted, and only the gentle slope portions 63B and 63C and the steep slope portions 64B and 64C are illustrated.

Points PB1 and PC1 respectively represent the positions of the front end portions (connecting portions between the steep slope portions 64B and 64C and the tip end portions 65B and 65C (not illustrated)) of the steep slope portions 64B and 64C. Points PB2 and PC2 respectively represent the positions of the connecting portions between the gentle slope portions 63B and 63C and the steep slope portions 64B and 64C. Points PB3 and PC3 respectively represent the positions of rear end portions (connecting portions between the gentle slope portions 63B and 63C and the base end portions 62B and 62C (not illustrated)) of the gentle slope portions 63B and 63C.

A pitch P represents a distance between the steep slope portion 64B and the steep slope portion 64C of each of the louver boards 61B and 61C adjacent to each other (an interval in the up-down direction between two adjacent louver boards). That is, the pitch P represents a distance between the point PB1 and the point PC1. In order to satisfy the conditions of the safety standard as a medical monitor, and since there are many structural constraints, it is desirable to minimize the pitch P.

An opening dimension H represents a distance (interval in the up-down direction between the gentle slope portions of two adjacent louver boards) between the gentle slope portion 63B of the louver board 61B and the gentle slope portion 63C of the louver board 61C. The opening dimension H represents a dimension in the up-down direction of the widest part in the up-down direction of each opening 71 through which the air of the inner louver 42 passes. The opening dimension H is desirably as large as possible in order to improve heat dissipation.

An opening dimension H′ represents a distance (interval in the up-down direction between the steep slope portions of two adjacent louver boards) between the steep slope portion 64B of the louver board 61B and the steep slope portion 64C of the louver board 61C. The opening dimension H′ represents a dimension in the up-down direction of the narrowest part in the up-down direction of each opening 71 through which the air of the inner louver 42 passes. The opening dimension H′ is desirably as large as possible in order to improve heat dissipation.

A distance L represents a distance from a point where a water droplet from the louver board 61B falls on the steep slope portion 64C of the louver board 61C to the point PC2. The distance L is desirably as large as possible so that the water droplet dropped on the steep slope portion 64C and the rebound thereof do not reach the range of the gentle slope portion 63C. Note that a condition is that the distance L is set to 0 or more, that is, a drop point of the water droplet from the louver board 61B is in the range of the steep slope portion 64C of the louver board 61C. A y axis in the up-down direction in FIG. 12 represents an arrangement direction of each of the louver boards 41A to 41E of the inner louver 42, and represents the gravity direction in the monitor 1 (the fall angle is 0 degrees) in the upright state. Therefore, assuming that the fall angle of the monitor 1 is Y, the gravity direction with respect to the louver boards 61B and 61C changes with respect to the y-axis direction according to the fall angle γ of the monitor 1. In FIG. 12, the gravity direction (water droplet falling direction) when the fall angle of the monitor 1 is γ is indicated by an arrow.

A water droplet falling height h represents a falling distance of a water droplet falling from the louver board 61B to the louver board 61C. In order to reduce the rebound of the water droplet (potential energy of the falling water droplet), the water droplet falling height h is desirably as small as possible.

An inclination angle A represents an inclination angle of the steep slope portions 64B and 64C with respect to the horizontal direction in the front-rear direction in the monitor 1 in the upright state. The inclination angle A is desirably as large as possible so that a water droplet easily flows in the forward direction and the rebound does not enter the inside of the monitor 1.

On the basis of the above conditions (and requests), the structure of the inner louver 42 is determined such that the position of the point PC2 that is the intersection of the gentle slope portion 63C and the steep slope portion 64C of the louver board 61C is within an allowable range AR (excluding the line segment PV-PC3) that is the range of a right triangle having a point PV, a point PL, and the point PC3 as vertices.

That is, the inclination angle A is required to be larger than the fall angle γ of the monitor 1. The fall angle γ of the monitor 1 is an angle required in a drip-proof test corresponding to a grade that the monitor 1 should satisfy among IPX0 to IPX8, IPX0 to IPX8 being representative of a grade of the drip-proof performance (waterproof protection grade) in the medical safety standard. For example, in a case where the inner louver 42 is designed to have IPX2 drip-proof performance as the waterproof protection grade of the monitor 1, the fall angle γ of the monitor 1 required in the drip-proof test is 15 degrees. However, assuming that the stand supporting the monitor 1 can fall forward (tilt is possible) by up to 10 degrees, it is necessary to consider a fall angle (tilt angle) by the stand, and thus, an angle of 25 degrees is obtained by calculating a total for those angles, and the angle of 25 degrees is assumed as the fall angle γ of the monitor 1. In a case where the inclination angle A is increased with respect to the fall angle Y of the monitor 1 assumed as described above, if the inclination angle of the monitor 1 is γ or less, the steep slope portions 64B and 64C of the louver boards 61B and 61C are always in a state of being inclined obliquely downward toward the rear direction with respect to the horizontal direction. Therefore, water droplets that have fallen on the steep slope portions 64B and 64C flow toward the outside of the monitor 1.

On the other hand, in a case where the inclination angle A of the steep slope portions 64B and 64C of the inner louver 42 is set to be larger than the fall angle γ, the larger the inclination angle A, the smaller the opening dimension H′, and the lower the heat dissipation. However, in the inner louver 42, the louver boards 61B and 61C are configured by the gentle slope portions 63B and 63C and the steep slope portions 64B and 64C having different inclination angles, so that the opening dimension H can be designed not to become smaller even in a case where the opening dimension H′ becomes smaller. Therefore, if the inclination angle A is smaller than a predetermined upper limit value, the reduction of heat dissipation is suppressed.

A straight line passing through the point PV and the point PC3 of the allowable range AR is determined by the fall angle γ of the monitor 1 and a depth of the monitor 1.

The point PL in the allowable range AR is determined as an intersection of a draft angle line passing through the point PC3 and a line passing through the point PB1 and forming an angle γ with respect to the vertical direction.

The allowable range AR is determined by the following flow of 1 to 9 as an example.

1. The point PC1 is set as an origin PC1.

2. The depth (a line parallel to the vertical direction (y-axis direction) passing through the point PC3: a depth line) is determined by the structural constraints.

3. A line having the angle γ is drawn from the origin PC1, and the intersection point with the depth line is defined as the point PC3.

4. The pitch P is determined from the structural constraints such as the heat dissipation and the drip-proof property.

5. The point PB1 is determined from the pitch P.

6. The line having the angle γ with respect to the vertical direction is drawn from the point PB1, and an intersection point with the line segment PC1-PC3 is defined as the point PV.

7. The draft angle line is drawn from the point PC3 in the horizontal direction (x-axis direction).

8. An intersection between the draft angle line and the line segment PB1-PV is defined as the point PL.

9. A range connecting the point PV, the point PC3, and the point PL is defined as the allowable range AR.

Note that, in a case where the point PC2 is set in the vicinity of the point PC3 in the allowable range AR, the gentle slope portion 63C is not substantially provided, but this may be the case.

### <Inclination of the Inner Louver 41 and the Inner Louver 42 in the Left-Right Direction>

For example, like the inner louver 41 illustrated in FIG. 5, each of the louver boards of the inner louver 41 (the louver boards corresponding to each of the louver boards 61A to 61E of the inner louver 42 are denoted by the same reference numerals) is disposed so as to be inclined obliquely downward toward the left. In a case where both the inner louvers 41 and 42 are viewed from the rear side as illustrated in FIGS. 2 and 3, each of the louver boards 61A to 61E of the inner louver 41 and each of the louver boards 61A to 61E of the inner louver 62 are arranged in a “chevron” shape (a state in which the louver boards are inclined downward toward both ends) by the corresponding louver boards.

With this arrangement, the inclination is adapted to an inclination angle in the left-right direction required in the drip-proof test corresponding to the grade that the monitor 1 should satisfy among IPX0 to IPX8, IPX0 to IPX8 being the grades (waterproof protection grades) of the drip-proof performance.

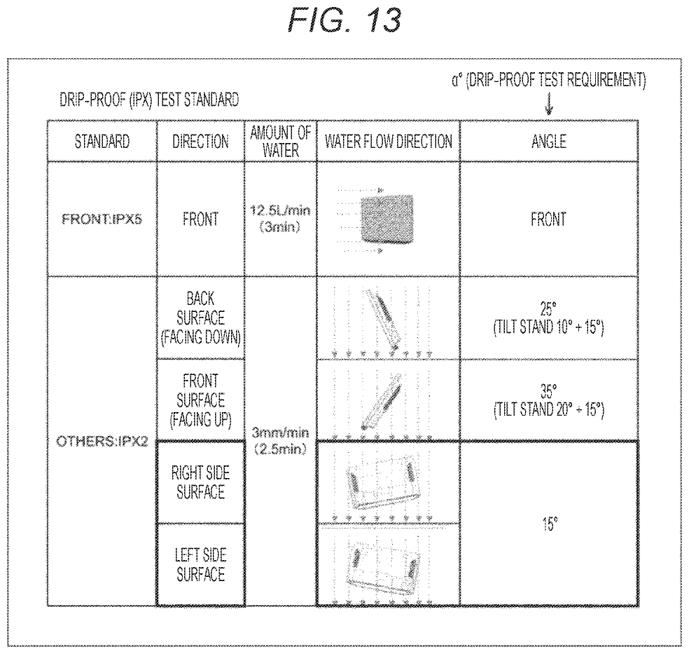

FIG. 13 is a diagram describing the inclination angle in the left-right direction required in the drip-proof test corresponding to IPX2 as the drip-proof performance. FIG. 13 illustrates conditions of the drip-proof test of a type other than the inclination angle in the left-right direction, but the conditions of the drip-proof test with respect to the inclination angle in the left-right direction in IPX2 are shown in a part surrounded by a thick line. With this arrangement, the drip-proof test is performed in a case where the right side surface (corresponding to the left side surface in the present specification) of the monitor 1 is inclined downward by 15 degrees with respect to the horizontal direction and in a case where the left side surface (corresponding to the right side surface in the present specification) of the monitor 1 is inclined downward by 15 degrees with respect to the horizontal direction. Hereinafter, adaptability of the inner louver 41 for the latter drip-proof will be described. Note that, in a case where the inner louver 41 is adapted to the latter drip-proof test, the inner louver 42 is also adapted to the same adaptive test, and the inner louvers 41 and 42 are also adapted to the latter drip-proof test due to a left-right symmetry.

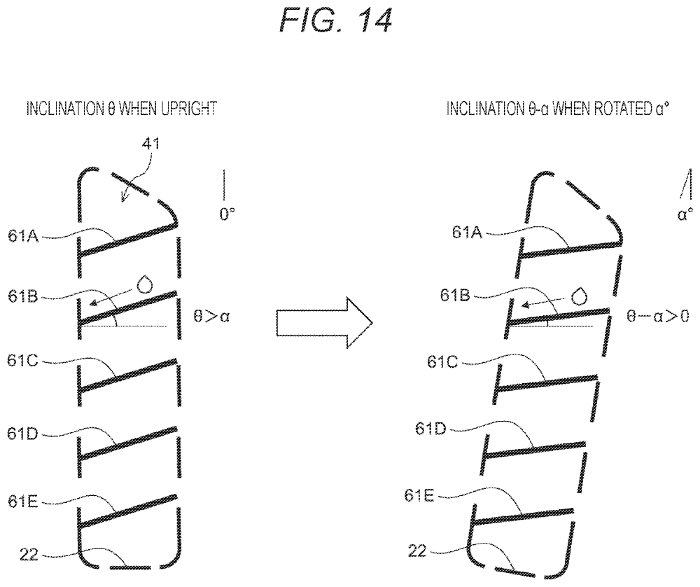

FIG. 14 is a view simply illustrating the inner louver 41 of the intake portion 13 from the rear side. The inner louver 41 on the left side in the drawing represents a case where the monitor 1 is in the upright state, and the inner louver 41 on the right side in the drawing represents a case where the monitor 1 is inclined at the inclination angle required in the drip-proof test of IPX2. Note that a state in which the right side surface of the monitor 1 is inclined downward by a degrees is defined as a state at the time of a rotation (a state in which the monitor 1 is rotated by a degrees around an axis in the front-rear direction).

In a case where the monitor 1 is in the upright state (in a case where α is 0 degrees), it is assumed that an inclination angle of each of the louver boards 61A to 61E of the inner louver 41 is θ degrees. The inclination angle of each of the louver boards 61A to 61E of the inner louver 41 means an inclination angle with respect to the horizontal direction of a plane direction (direction along the plane) in the left-right direction of the gentle slope portions 63A to 63E or the steep slope portions 64B to 64E of each of the louver boards 61A to 61E.

In the state of the monitor 1 at the time of a rotation, the inclination angle of each of the louver boards 61A to 61E of the inner louver 41 is θ-α degrees.

By designing such that the inclination angle θ of each of the louver boards 61A to 61E is larger than α degrees with respect to the rotation angle α required in the drip-proof test, water droplets dropped on each of the louver boards 61A to 61E are always guided in the left direction, even in the state of the monitor 1 at the time of a rotation and even when the monitor 1 rotates by less than α degrees. Therefore, the water droplets that have fallen on each of the louver boards 61A to 61E of the inner louver 41 can be limited to flow on a uniquely determined path regardless of the inclination angle in the left-right direction of the monitor 1 (the inclination angle of the conditions of the drip-proof test), and can be appropriately guided to the outside of the monitor 1. Note that each of the louver boards 61A to 61E of the inner louver 41 may not be inclined in the gravity direction (downward) toward the left, but may be inclined in the gravity direction toward the right.

### <Description of the Outer Louvers 31 and 32>

Structures and the like of the outer louvers 31 and 32 illustrated in FIGS. 1 and 2 and the like will be described using the outer louver 31 of the intake portion 13 as an example.

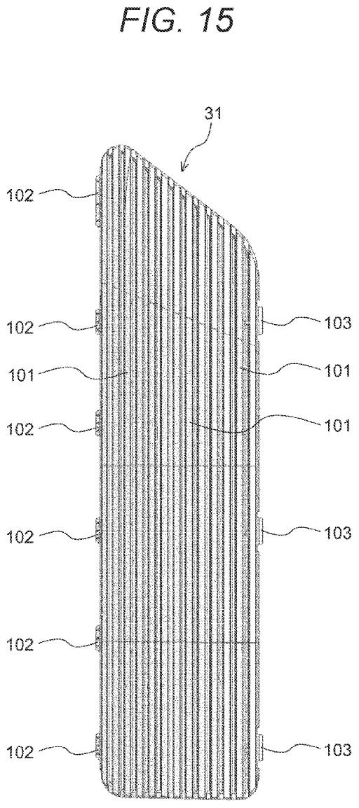

FIG. 15 is a back view illustrating the outer louver 31 from the rear side (front side). Note that terms indicating positions and directions such as front, rear, upper, lower, left, and right with respect to outer louver 31 are used on the assumption that the outer louver 31 is attached to rear cover 21 of the monitor 1.

The outer louver 31 in FIG. 15 is detachably attached to the opening portion 22 of the rear cover 21. The outer louver 31 has a louver door structure in which a large number of thin louver boards 101 are arranged at predetermined intervals in the horizontal direction (left-right direction). Each louver board 101 is disposed along the vertical direction (up-down direction), and is integrally connected (for example, integrally formed) with a synthetic resin or the like to a frame (not illustrated) surrounding a peripheral edge portion. A plurality of (six) projections 102 is formed on the left side surface which is a part of a peripheral edge portion of the outer louver 31. When the outer louver 31 is attached to the opening portion 22 of the rear cover 21, the projection 102 is engaged (fitted) with a peripheral edge portion of the opening portion 22. A plurality of (three) locking portions 103 is formed on the right side surface which is a part of the peripheral edge portion of the outer louver 31. When the outer louver 31 is attached to the opening portion 22 of the rear cover 21, the locking portion 103 is engaged (locked) with the peripheral edge portion of the opening portion 22.

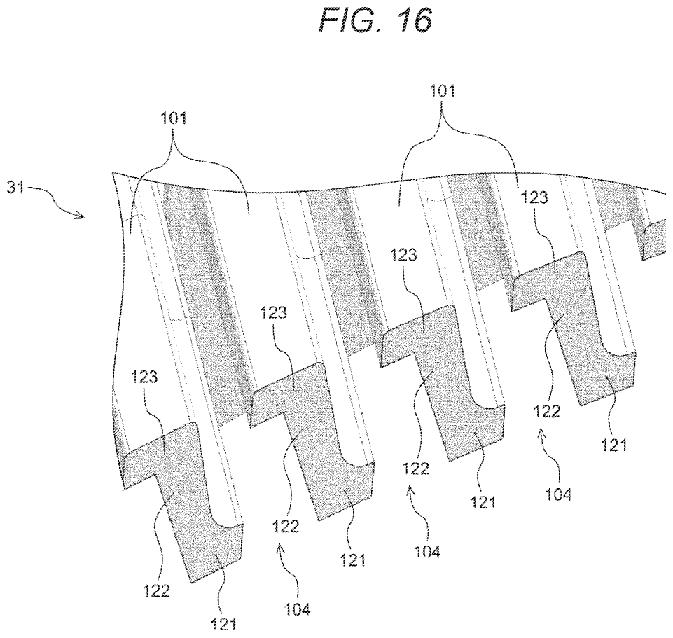

FIG. 16 is a perspective view from below illustrating a case where α cross-section of the outer louver 31 is cut along the horizontal direction (the left-right direction and the front-rear direction).

In FIG. 16, each of the louver boards 101 of the outer louver 31 is formed in a thin board shape extending in the up-down direction, and the louver boards 101 are disposed at predetermined intervals. An opening 104 is formed between the two adjacent louver boards 101 as a ventilation path through which air passes from the outside of the monitor 1 to the inner louver 41. That is, in the outer louver 31, the openings 104 are arranged along the left-right direction as a plurality of ventilation paths having a longitudinal cross-sectional shape with the up-down direction as the longitudinal direction. Between the adjacent openings 104, a louver board 101 is disposed as a partition that partitions them.

Note that an opening similar to the opening 104 through which air passes from the inner louver 42 to the outside of the monitor 1 is formed in the outer louver 32 attached to the exhaust portion 14. Here, assuming that the longitudinal direction of the opening 104 is a third direction, a plurality of the openings 104 is arranged along a fourth direction different from the third direction. In the present embodiment, the fourth direction is a direction orthogonal to the third direction, but in the present technology, the fourth direction may be a direction other than the direction orthogonal to the third direction (a direction different from the third direction). In the present embodiment, the third direction is a direction along the vertical direction (gravity direction), and is a direction along the second direction along which the plurality of openings 71 (see FIG. 9) of the inner louver 41 is arranged. In the present technology, the third direction may be a direction along a direction other than the second direction, or may be a direction along a direction other than the gravity direction. In the present embodiment, the fourth direction is a direction along the horizontal direction and is a direction along the first direction which is the longitudinal direction of the opening 71 of the inner louver 41. In the present technology, the fourth direction may be a direction along a direction other than the first direction, or may be a direction along a direction other than the horizontal direction.

The louver board 101 has a base end portion 121, an intermediate portion 122, and a front surface portion 123. The base end portion 121 is a part where the board surface is disposed along the left-right direction. The intermediate portion 122 is a part extending forward from one end portion (for example, a left end portion) of the base end portion. The front surface portion 123 is a part extending along the left-right direction (for example, toward the left direction) from the front end portion of the intermediate portion 122. The rear side board surface of the front surface portion 123 is disposed at a position substantially flush with the front surface of the rear cover 21 when the outer louver 31 is attached to the opening portion 22 of the rear cover 21. Therefore, the front surface of the outer louver 31 has a shape following the front surface of the rear cover 21, and a step is hardly generated between the front surface of the rear cover 21 and the front surface of the outer louver 31.

According to the louver board 101 of the outer louver 31, while air flows through the opening 104, the path of water droplets linearly passing from the outside of the monitor 1 to the inner louver 41 is blocked by any one of the base end portion 121, the intermediate portion 122, and the front surface portion 123, except for water droplets from a specific direction. Therefore, water droplets from the outside of the monitor 1 are guided downward (in the gravity direction) by each louver board 101 of the outer louver 31, so that the outer louver 31 has a drip-proof action. Due to the double drip-proof action of the outer louver 31 and the inner louver 41, it is possible to realize the monitor 1 with a high waterproof protection grade having an excellent drip-proof action.

### <Mounting Structure of the Outer Louver 31>

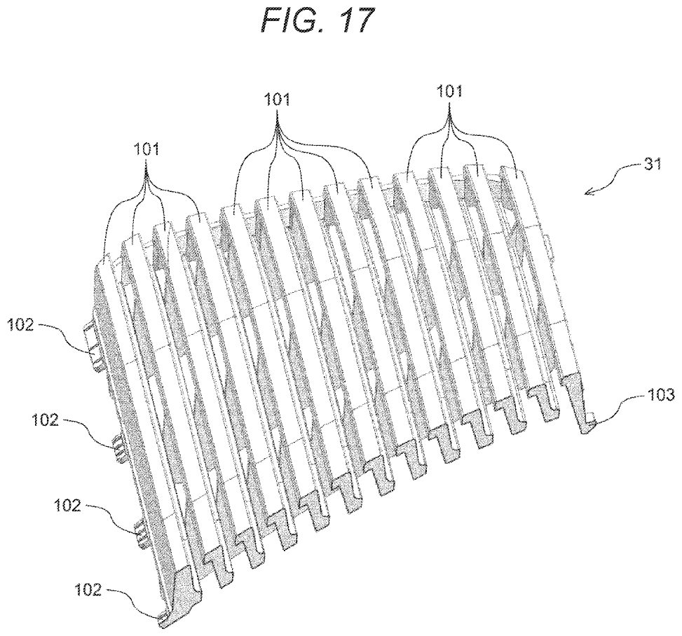

FIG. 17 is a view for describing a mounting structure for detachably mounting the outer louver 31 to the opening portion 22 of the rear cover 21. FIG. 17 illustrates the outer louver 31 cut by a cross-section passing through positions of the projection 102 formed on the left side surface of the outer louver 31 and the locking portion 103 formed on the right side surface. The projection 102 has a flat thin board-like shape and is formed so as to protrude leftward from a part of the left side surface (a side surface of the leftmost louver board 101) of the outer louver 31. The locking portion 103 has a wedge shape (tapered shape) and is formed so as to protrude rightward from a part of the right side surface (a side surface of the rightmost louver board 101) of the outer louver 31.

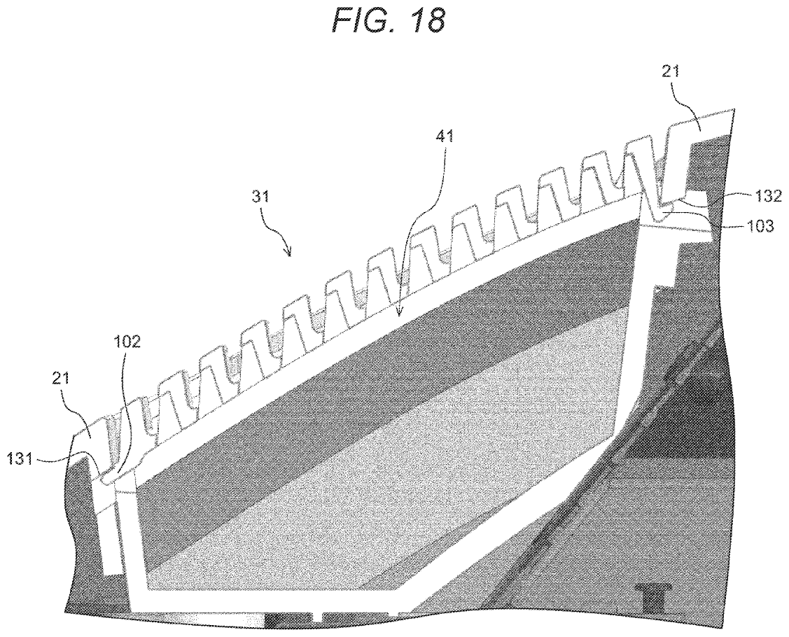

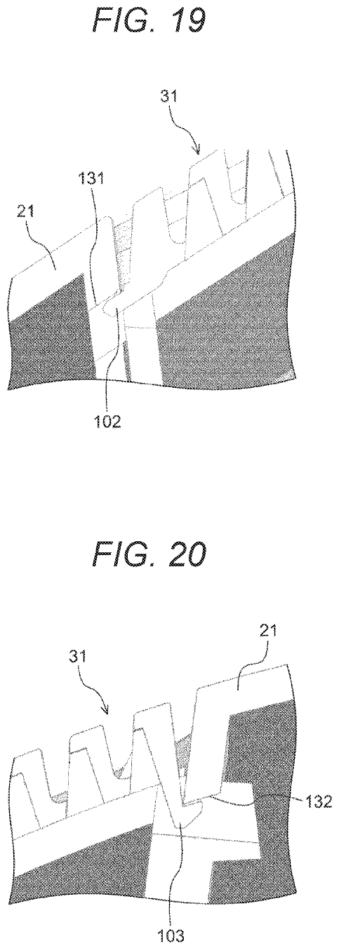

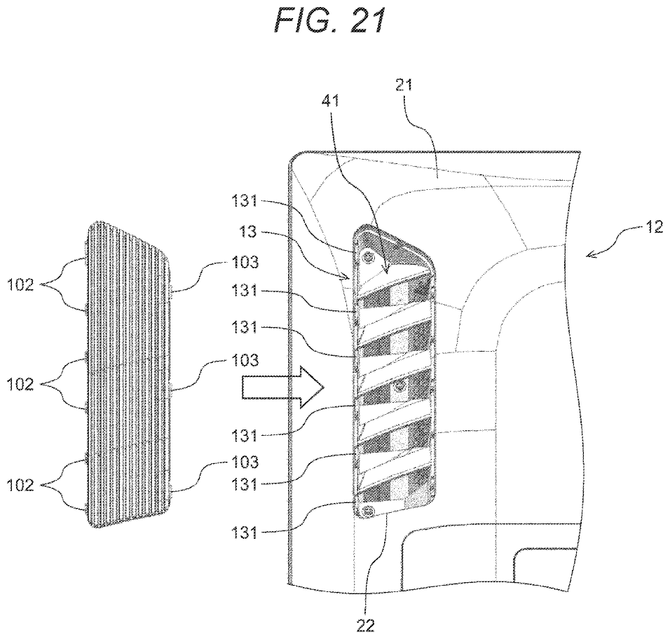

FIG. 18 is a drawing illustrating a periphery of the outer louver 31 cut by a cross-section passing through positions of the projection 102 and the locking portion 103 of the outer louver 31 in a state where the outer louver 31 is attached to the opening portion 22 of the rear cover 21. FIG. 19 is an enlarged cross-sectional view of a periphery of the projection 102 in FIG. 18, and FIG. 20 is an enlarged cross-sectional view of a periphery of the locking portion 103 in FIG. 18.

In FIGS. 18 and 19, the projection 102 of the outer louver 31 is fitted into a fitting hole 131 formed in a peripheral edge portion of the opening portion 22 of the rear cover 21. Therefore, a movement of the periphery of the projection 102 of the outer louver 31 in the front-rear direction with respect to the opening portion 22 of the rear cover 21 is restricted.

In FIGS. 18 and 20, the locking portion 103 of the outer louver 31 is fitted into and engaged with a locking hole 132 formed in the peripheral edge portion of the opening portion 22 of the rear cover 21. Therefore, a movement of the periphery of the locking portion 103 of the outer louver 31 in the front-rear direction with respect to the opening portion 22 of the rear cover 21 is restricted.

A movement in the front-rear direction with respect to a peripheral portion of the projection 102 and the locking portion 103 of the outer louver 31 is restricted, whereby the outer louver 31 is attached to the opening portion 22 of the rear cover 21.

### <Procedure for Attaching the Outer Louver 31>

FIGS. 21 to 23 are drawings illustrating a procedure when the outer louver 31 is attached to the opening portion 22 of the rear cover 21.

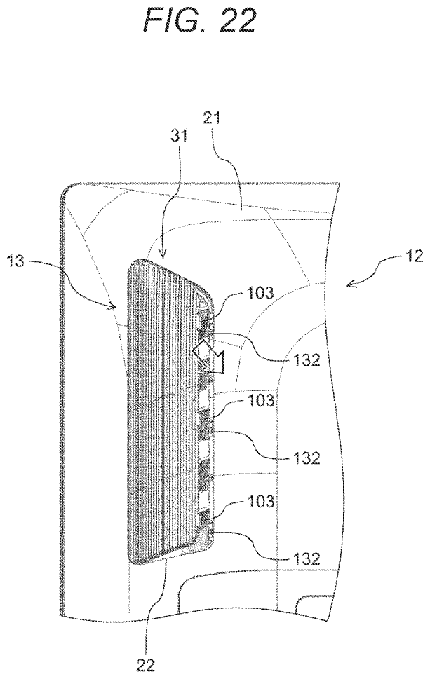

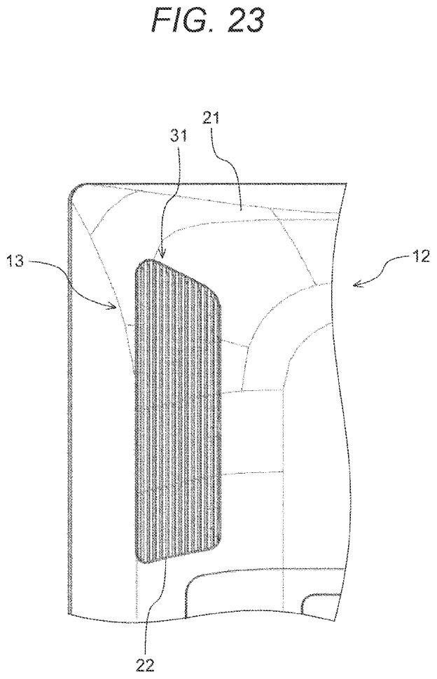

In FIG. 21, an operator inserts the plurality of projections 102 formed on the left side surface of the outer louver 31 into a plurality of fitting holes 131 of the opening portion 22 formed at positions corresponding to each of the projections. In FIG. 22, the operator pushes the right side surface side of the outer louver 31 into the opening portion 22 of the rear cover 21 in a state where the projections 102 of the outer louver 31 are inserted into the fitting holes 131 of the rear cover 21. Therefore, the plurality of locking portions 103 of the outer louver 31 is engaged with the locking holes 132 of the opening portion 22 formed at each of the corresponding positions, and is locked by the locking holes 132. In FIG. 23, the outer louver 31 is attached to the opening portion 22 of the rear cover 21 in a state where it cannot be easily removed, and is disposed to overlap the inner louver 41.

### <Procedure for Removing the Outer Louver 31>

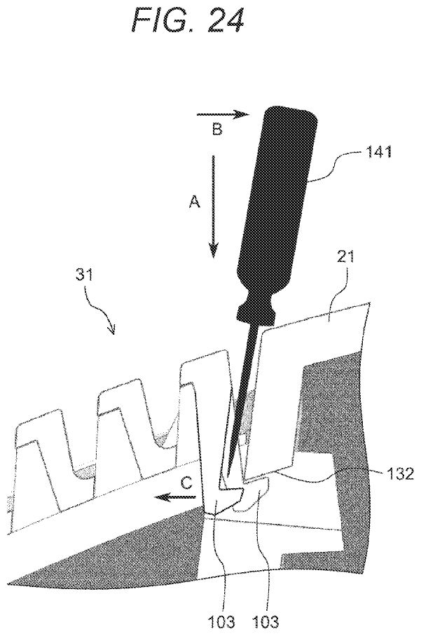

FIG. 24 is a view illustrating a procedure for removing the outer louver 31 from the opening portion 22 of the rear cover—21.

During normal use of the monitor 1 in a medical site, the cleaning work is performed without removing the outer louver 31. Since the case of removing the outer louver 31 is limited to a case where α specialized operator performs maintenance or periodic cleaning work of the monitor 1, the outer louver 31 has a structure that cannot be easily removed from the rear cover 21.

In FIG. 24, the operator inserts a screwdriver 141 into a gap between the outer louver 31 and the rear cover 21 in the vicinity of the position where the locking portion 103 of the outer louver 31 is disposed (operation indicated by an arrow A). Note that the operator may use a tool other than the screwdriver 141 having a thin tip end part. The operator moves a handle part of the screwdriver 141 whose tip portion is inserted to the vicinity of the locking portion 103 in the right direction (operation indicated by an arrow B), and moves the tip portion of the driver 141 in the left direction with a contact position between a peripheral portion of the opening portion 22 of the rear cover 21 and the screwdriver 141 as a fulcrum (operation indicated by an arrow C). Therefore, the locking portion 103 is detached from the locking hole 132, and the peripheral portion of the locking portion 103 rises from the opening portion 22. The operator also performs a similar operation on the other locking portions 103 to remove all the locking portions 103 from the locking holes 132. Thereafter, by pulling the outer louver 31 in the right direction, the operator removes the projection 102 on the left side surface of the outer louver 31 from the fitting hole 131 of the opening portion 22, and removes the outer louver 31 from the rear cover 21.

### <Cleaning Performance of the Rear Cover 21>

In a case where the monitor 1 is used in the medical site, cleaning is frequently performed for every operation unit or the like. Therefore, it is desirable that cleaning be performed in a short time and reliably. The structures of the intake portion 13 and the exhaust portion 14 of the monitor 1 also act advantageously in such cleaning work.

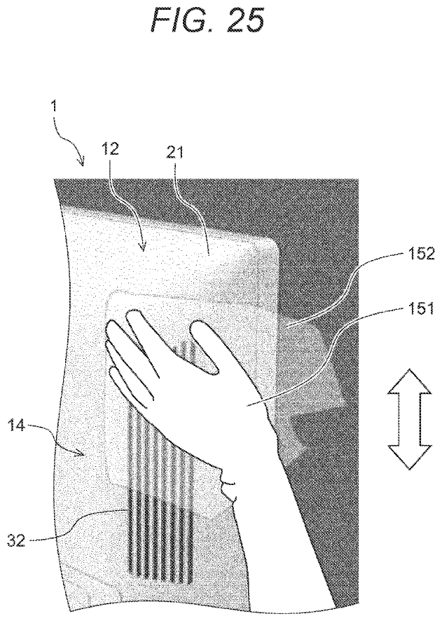

FIG. 25 is a drawing illustrating a state of work when the exhaust portion 14 (outer louver 31) of the back surface portion 12 of the monitor 1 is cleaned using the cloth.

In FIG. 25, an operator 151 brings a cloth 152 into contact with the outer louver 32 of the rear cover 21 and moves the cloth in the up-down direction (from the top to the bottom). In the part where the outer louver 32 is disposed, the front surface portions 123 (see FIG. 16 or the like) of each louver board 101 of the outer louver 32 are connected to the front surface of the rear cover 21 substantially without a step, and are disposed such that the longitudinal direction of each of the openings 104 (a longitudinal direction of each of the front surface portions 123) is the up-down direction. Therefore, the operator can move the cloth 152 in the up-down direction without resistance, and there is almost no step with respect to the up-down direction, so that a part that is not cleaned is hardly generated, and cleaning is reliably performed (excellent cleaning performance). Since a width of the outer louver 32 in the left-right direction is shorter than a width in the up-down direction, the number of movements of the cloth 152 in the up-down direction by the operator may be small, and an operation time is reduced (excellent cleaning performance).

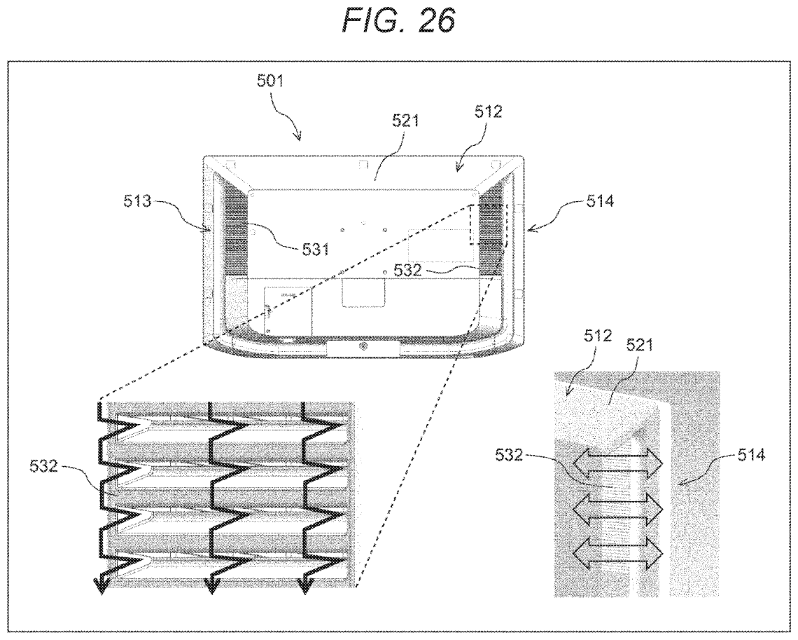

FIG. 26 is a view illustrating a state of work when the exhaust portion 514 (louver 532) of the monitor 501 of FIG. 6 to which the present technology is not applied is cleaned using a cloth. Note that, in the drawing, parts common to those in FIG. 6 are denoted by the same reference numerals, and the description thereof will be omitted.

In FIG. 26, the louver 532 formed on the back surface portion 512 (rear cover 521) of the monitor 501 has a louver structure (horizontal louver structure) in which a large number of openings extending in the left-right direction and a front surface portion are alternately arranged in the vertical direction. Note that, in a case where entry of water droplets from above into the monitor 501 is prevented by one louver 532, the horizontal louver structure is usually adopted as in the louver 532 in FIG. 26. In this case, an unevenness occurs in the up-down direction in the louver 532 as illustrated in the partially enlarged view in the lower left of the drawing. Therefore, in the case of performing the cleaning work using the cloth, the operator moves the cloth in the left-right direction. In a case where the louver 532 is long in the up-down direction, it is necessary to change the position in the up-down direction to which the cloth is applied. Therefore, as compared with the cleaning work of the monitor 1 to which the present technology is applied, the time and labor required for the cleaning work of the monitor 502 of FIG. 26 are large. Even in a case where the cover having the drip-proof performance disclosed in Patent Document 1 is attached to the housing, there is much unevenness, and the time and labor required for the cleaning work are large.

As described above, the outer louvers 31 and 32 illustrated in FIG. 1 and the like have a structure for guiding water droplets from the outside of the monitor 1 in the gravity direction, and may have any structure as long as the configuration has a similar action. The outer louvers 31 and 32 may not have a remarkable drip-proof action, and it is sufficient if the outer louvers 31 and 32 have an action of reducing the entry of water droplets into the inner louvers 41 and 42. For example, the outer louvers 31 and 32 may be covering members that cover the inner louvers 41 and 42 and have ventilation paths that allow ventilation between the outside of the monitor 1 and the inner louvers 41 and 42. Specifically, the outer louvers 31 and 32 may be board-shaped covering members in which ventilation paths having a circular shape, a rectangular shape, or the like are arranged at predetermined intervals in the up-down direction and the left-right direction.

Note that each of the outer louvers 31 and 32 may be configured as an integral component integrally formed with the rear cover 21. Each of the inner louvers 41 and 42 may be configured separately and detachably from the rear cover 21 or may be configured as an integral component integrally formed with the rear cover 21. Therefore, the present technology includes a mode in which one or both of the outer louvers 31 and 32 and the inner louvers 41 and 42 are configured to be detachable from the rear cover 21. The present technology includes a mode in which both the outer louvers 31 and 32 and the inner louvers 41 and 42 are configured as integral components with respect to the rear cover 21.

The present technology can be applied to, for example, a medical device other than the monitor 1, such as a medical device used in an endoscopic surgical system or the like. In an endoscopic surgical system, various medical devices are used, such as an endoscope, a light source device that supplies illumination light to the endoscope, a camera control unit that controls an imaging unit of the endoscope and performs processing or the like on an image captured by the imaging unit, a control device that controls a treatment tool used in endoscopic surgery, and a pneumoperitoneum device that supplies gas into a body cavity. By providing the ventilation portion having a similar structure to the intake portion 13 and the exhaust portion 14 of the monitor 1 of FIG. 1 in the housing of these medical devices, it is possible to provide in the housing the ventilation portion having an excellent drip-proof property and a simple structure. The present technology is also applicable to devices other than medical devices.

The present technology can also have the following configurations.

(1)

A medical device including
an inner louver that is a ventilation path for ventilation between an outside and an inside of a housing and has a structure in which a plurality of ventilation paths having a longitudinal cross-sectional shape with a predetermined first direction as a longitudinal direction is arranged along a second direction different from the first direction; and
a covering member that covers the inner louver from the outer side of the housing, the covering member including a plurality of ventilation paths that allows ventilation between the outside of the housing and the inner louver.

(2)

The medical device according to (1), in which
the second direction is a direction orthogonal to the first direction.

(3)

The medical device according to (1) or (2), in which
the first direction is a direction along a direction orthogonal to a gravity direction.

(4)

The medical device according to (1), (2), or (3), in which
the second direction is a direction along the gravity direction.

(5)

The medical device according to any one of (1) to (4), in which
the inner louver has a partition that partitions each of the plurality of ventilation paths.

(6)

The medical device according to (5), in which
the partition has an inclined surface inclined in the gravity direction from the inside of the housing toward the outside of the housing.

(7)

The medical device according to (6), in which
the inclined surface of the partition is inclined in the gravity direction toward a predetermined direction in the first direction.

(8)

The medical device according to (6) or (7), in which
the inclined surface includes a first inclined surface and a second inclined surface having different inclinations.

(9)

The medical device according to (8), in which
the first inclined surface is smaller in inclination than the second inclined surface and is disposed closer to the inner side of the housing than the second inclined surface.

(10)

The medical device according to (9), in which
the second inclined surface of the partition is disposed at a position through which a water droplet dropped in the gravity direction from the another partition adjacent to the partition passes.

(11)

The medical device according to any one of (1) to (10), in which the inner louver is integrally formed with the housing.

(12)

The medical device according to any one of (1) to (10), in which
the inner louver is attachable to and detachable from the housing.

(13)

The medical device according to any one of (1) to (12), in which
the covering member is attachable to and detachable from the housing.

(14)

The medical device according to any one of (1) to (13), in which
a front surface of the covering member has a shape following a front surface of the housing.

(15)

The medical device according to any one of (1) to (14), in which
the covering member has a structure in which the plurality of ventilation paths having a longitudinal cross-sectional shape with a direction along the second direction as the longitudinal direction is arranged along the first direction.

(16)

The medical device according to any one of (1) to (14), in which
the covering member has a structure in which the plurality of ventilation paths having a longitudinal cross-sectional shape with a direction along the gravity direction as the longitudinal direction is arranged along a direction different from the gravity direction.

(17)

The medical device according to any one of (1) to (16), in which
the covering member has a partition that partitions each of the plurality of ventilation paths of the covering member.

(18)

The medical device according to any one of (1) to (17), in which
the covering member has a structure that guides water droplets from the outside of the housing in the gravity direction.

(19)

The medical device according to any one of (1) to (18), in which
the inner louver and the covering member are disposed in the housing on a back surface portion of a monitor.

### REFERENCE SIGNS LIST

1, 501 Monitor
11 Front surface portion
12 Back surface portion
13 Intake portion
14 Exhaust portion
21 Rear cover
22, 23 Opening portion
31, 32 Outer louver
41, 42 Inner louver
61A to 61E, 102 Louver board
62A to 62E Base end portion
63A to 63E Gentle slope portion
64A to 64E Steep slope portion
65A to 65E Tip end portion
102 Projection
103 Locking portion
104 Opening
121 Base end portion
122 Intermediate portion
123 Front surface portion

1. A medical device comprising:
an inner louver that is a ventilation path for ventilation between an outside and an inside of a housing and has a structure in which a plurality of ventilation paths having a longitudinal cross-sectional shape with a predetermined first direction as a longitudinal direction is arranged along a second direction different from the first direction; and
a covering member that covers the inner louver from an outer side of the housing, the covering member including a plurality of ventilation paths that allows ventilation between the outside of the housing and the inner louver.

2. The medical device according to claim 1, wherein
the second direction is a direction orthogonal to the first direction.

3. The medical device according to claim 1, wherein
the first direction is a direction along a direction orthogonal to a gravity direction.

4. The medical device according to claim 1, wherein
the second direction is a direction along the gravity direction.

5. The medical device according to claim 1, wherein
the inner louver has a partition that partitions each of the plurality of ventilation paths.

6. The medical device according to claim 5, wherein
the partition has an inclined surface inclined in the gravity direction from the inside of the housing toward the outside of the housing.

7. The medical device according to claim 6, wherein
the inclined surface of the partition is inclined in the gravity direction toward a predetermined direction in the first direction.

8. The medical device according to claim 6, wherein
the inclined surface includes a first inclined surface and a second inclined surface having different inclinations.

9. The medical device according to claim 8, wherein
the first inclined surface is smaller in inclination than the second inclined surface and is disposed closer to the inner side of the housing than the second inclined surface.

10. The medical device according to claim 9, wherein
the second inclined surface of the partition is disposed at a position through which a water droplet dropped in the gravity direction from the another partition adjacent to the partition passes.

11. The medical device according to claim 1, wherein
the inner louver is integrally formed with the housing.

12. The medical device according to claim 1, wherein
the inner louver is attachable to and detachable from the housing.

13. The medical device according to claim 1, wherein
the covering member is attachable to and detachable from the housing.

14. The medical device according to claim 1, wherein
a front surface of the covering member has a shape following a front surface of the housing.

15. The medical device according to claim 1, wherein
the covering member has a structure in which the plurality of ventilation paths having the longitudinal cross-sectional shape with a direction along the second direction as the longitudinal direction is arranged along the first direction.

16. The medical device according to claim 1, wherein
the covering member has a structure in which the plurality of ventilation paths having the longitudinal cross-sectional shape with a direction along the gravity direction as the longitudinal direction is arranged along a direction different from the gravity direction.

17. The medical device according to claim 1, wherein
the covering member has a partition that partitions each of the plurality of ventilation paths of the covering member.

18. The medical device according to claim 1, wherein
the covering member has a structure that guides a water droplet from the outside of the housing in the gravity direction.

19. The medical device according to claim 1, wherein
the inner louver and the covering member are disposed in the housing on a back surface portion of a monitor.
